(19) United States
(12) Patent Application Publication
(10) Pub. No.: US 2008/0048685 A1
(43) Pub. Date: Feb. 28, 2008

(54) Probe card having vertical probes

(75) Inventors: Ka Ng Chui, Menlo Park, CA (US); Hyoseok Daniel Yang, Santa Clara, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Corad Technology Inc., Santa Clara, CA (US)

(21) Appl. No.: 11/511,843

(22) Filed: Aug. 28, 2006

(51) Int. Cl. G01R 31/02

(52) U.S. Cl. 324/754

(57) ABSTRACT

A probe card includes a first probe plate having a first plurality of tapered apertures formed therein. Each of the tapered apertures has a first opening that is smaller than a second opening. The first openings and the second openings are on opposite surfaces of the first probe plate. The probe card further includes a second probe plate having a second plurality of tapered apertures formed therein. Each of the tapered apertures has a first opening that is smaller than a second opening. The first openings and the second openings are on opposite surfaces of the second probe plate. The surfaces having the second openings are disposed adjacent to one another. Pairs of the tapered apertures of the first and second probe plates substantially align. The probe card further includes a plurality of probes, wherein each of the probes is disposed in one of the pairs of the tapered apertures.

### BACKGROUND OF THE INVENTION

The present invention relates to integrated circuit technology. More particularly, the present invention relate to a test method and test apparatus for integrated circuit technology.

Integrated circuits (ICs) are typically tested prior to being used in an application, such as a circuit board. IC testing is often performed on wafers prior to packaging, after the ICs are packaged, and are often tested once soldered onto a circuit board. Finished products that include ICs are also often tested prior to shipping to consumers, and these finished products tests often further test of the ICs of these products.

Testing an IC at the wafer level typically includes contacting a probe card to pads on the IC and driving electrical signals into and receiving electrical signal from the IC. More specifically, the probe card's probes are configured to contact to the bond pads of the IC to drive and receive the electrical signals. The electrical signals received from the IC are typically generated by the IC in response to the electrical signal driven into the IC by the probe card. The electrical signals driven into the probe card and the IC are often generated by a signal generator, such as an automated test equipment (ATE) machine. The ATE machine may also be configured to receive the electrical signal from the IC via the probe card and compare the received electrical signal with known good (i.e., passing) and/or bad (i.e., failing) test patterns to determine whether the IC will be packed or rejected from packaging.

Relatively early generation probe cards were configured to contact and test a single IC (or die) on a wafer. These early probe cards often included tungsten probes that were substantially horizontally disposed and bent at the tips of the probes to contact the bond pads of the IC. Latter versions of these probe cards often included sets of probes that were often diagonally disposed to test two or more ICs in a single touch down of the probe card to the wafer. One draw back of both of these early generation probe cards is the limited number of ICs that can be tested in a single touch down. This draw back has become significant as IC manufacturer's would like to test all or a substantial percentage of the ICs on a wafer in a single touch down of the probe card to the wafer.

Therefore, new probe card methods and new probe apparatus are needed for testing wafers wherein a relatively large percentage of ICs on a wafer are tested in a single touch down of the probe card to the wafer.

### BRIEF SUMMARY OF THE INVENTION

The present invention provides a new test method and test apparatus for integrated circuit technology. More particularly, the present invention provides a probe card configured to transfer test signal to and receive test signal from an integrated circuit.

According to one embodiment of the present invention, the probe card includes a first probe plate having a first plurality of tapered apertures formed therein. Each of the tapered apertures has a first opening that is smaller than a second opening. The first openings and the second openings are on opposite surfaces of the first probe plate. The probe card further includes a second probe plate having a second plurality of tapered apertures formed therein. Each of the tapered apertures has a first opening that is smaller than a second opening. The first openings and the second openings are on opposite surfaces of the second probe plate. The surfaces having the second openings are disposed adjacent to one another. Pairs of the tapered apertures of the first and second probe plates substantially align. The probe card further includes a plurality of probes, wherein each of the probes is disposed in one of the pairs of the tapered apertures.

According to a specific embodiment of the present invention, the surface of the second probe plate that includes the first openings is a first surface of the probe card, and a second end of each of the probes is configured to extend from the first surface of the probe card.

According to another specific embodiment, the probe card further includes a space transformer that includes a plurality of pads disposed on a first surface of the space transformer, wherein each of the pads is configured to contact a first end of each of the probes. Each probe includes a lateral support that is configured to permit the force applied to the probe by the space transformer to be different than the force applied to the probe by a bond pad of an integrated circuit. According to a specific embodiment, a portion of each probe between the space transformer and the lateral support is constrained with a higher compression force than a compression force applied to the probe by a bond pad. The space transformer includes a second plurality of pads disposed on a second surface, which is disposed opposite the first mentioned surface of the space transformer.

According to a specific embodiment of the present invention, the probe card further includes a printed circuit board (PCB) coupled to the space transformer, wherein the PCB includes a plurality of pads, which is configured to respectively couple to the second plurality of pads of the space transformer. The density of the plurality of pads of the PCB is less than a density of the first plurality of the pads of the space transformer.

According to another specific embodiment of the present invention, each probe includes a lateral support that is configured to couple to a surface of the first probe plate that includes the first opening of the first probe plate. The lateral support of each of the probes is configured to inhibit the probe from dislodging from the first and second probe-plates. The lateral support is straight, curved, and/or has a spring configuration. Each of the probes includes a top portion that has a spring configuration and the top portion is configured to flex if the probe is pressed by the space transformer. The top portion is straight, coiled, or serpentined. Each probe includes a bottom portion that has a spring configuration and the bottom portion is configured to flex if the probe presses a bond pad of an integrated surface. The bottom portion is straight, coiled, or serpentined. The first and the second pluralities of tapered apertures of the top and bottom-probe plates are formed by laser ablation.

A better understanding of the nature and advantages of the present invention may be gained with reference to the following detailed description and the accompanying drawings.

### BRIEF DESCRIPTION OF THE DRAWINGS

FIGS. 1A and 1B are simplified side and bottoms views of a probe card according to one embodiment of the present invention;

FIG. 2 is an enlarged, cross-sectional view of a portion of the probe card shown FIGS. 1A and 1B;

FIG. 3 is a simplified side view of a variety of probes according to a variety of embodiments of the present invention;

FIG. 4 is a simplified cross-sectional view of a portion of a probe card according to another embodiment of the present invention;

FIG. 5 is a simplified cross-sectional view of a portion of a probe card according to another embodiment of the present invention; and

FIG. 6 is a simplified cross-sectional view of a probe card according to another embodiment of the present invention.

### DETAILED DESCRIPTION OF THE INVENTION

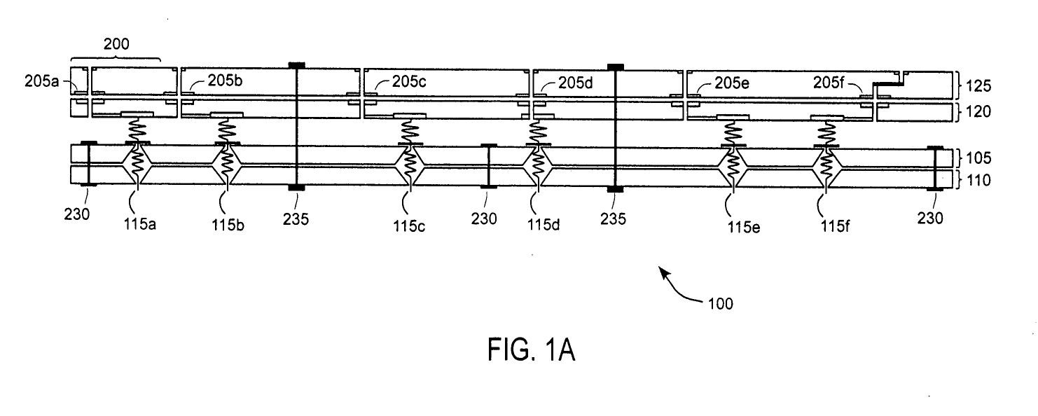

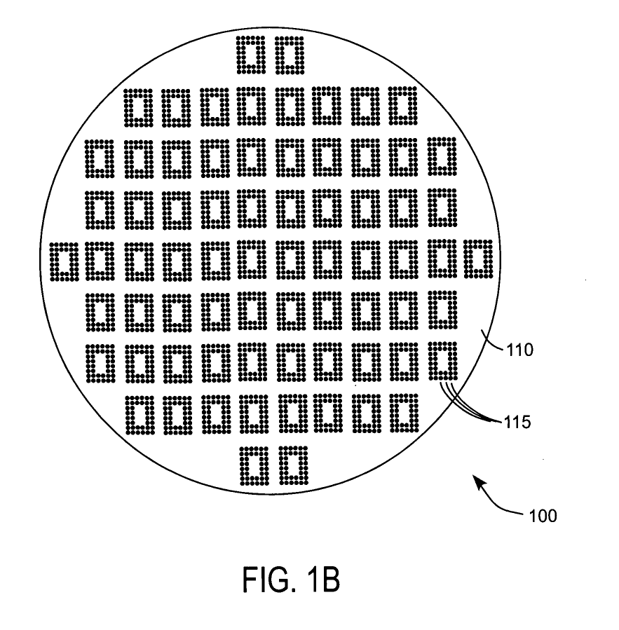

FIGS. 1A and 1B are simplified side and bottoms views of a probe card 100 according to one embodiment of the present invention. The probe card includes a top probe plate 105, a bottom probe plate 110, and a plurality of probes 115. The probes are labeled with the base reference numeral 115 and an alphabetic suffix. The probe card may also include space transformer 120 and a printed circuit board (PCB) 125. For convenience, probe card 100 is not shown to scale in FIGS. 1A and 1B but is shown for convenience.

The plurality of probes 115 is be configured to contact one or more of the ICs on a wafer. According to a specific embodiment of the present invention, the plurality of probes is configured to contact all of the ICs on the wafer so that all the ICs on the wafer may be tested in a single touch down of the probe card to the wafer. More specifically, the plurality of probes may be configured to contact the bond pads of the ICs on a wafer. Each probe may be configured to contact one bond pad of an IC. The probes may be configured to contact one or more of the bond pads of an IC. It should be understood that the pattern of probes shown in FIGS. 1A and 1B is exemplary, and that the probes may be arranged in nearly any pattern to substantially match the bond pads of an IC.

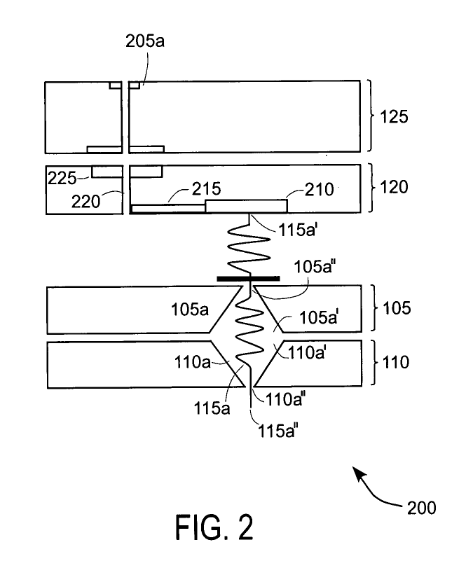

FIG. 2 is an enlarged, cross-sectional view of a portion 200 (see FIG. 1A) of probe card 100. For convenience, one probe 115a is shown in portion 200 in FIG. 2. It should be understood that each of the probes may be similarly disposed in the probe card. According to one embodiment of the present invention, probe 115a is disposed in a first hole 105a formed in the top probe plate and a second hole 110a formed in the bottom probe plate. The holes of the top and bottom probe plates may be substantially vertically aligned so that the probe is substantially vertically oriented.

According to one embodiment of the present invention, each of the holes (e.g., holes 105a and 110a) formed in the top and bottom probe plates are formed via a laser ablation (or laser drilling) process. In a typical laser drilling process, at the surface on which the laser enters the material being drilled, the entry portion (e.g., entry portion 105a′) of the hole is larger than the exit portion (e.g., exit portion 105a″) of the hole. The holes may be substantially round or oblong. For example, if the holes are oblong the entrance portion or the exit portion may be 100 microns by 30 microns or the like along the longest and shortest open portions of the entrance portion or the exit portion. According to one embodiment, the top probe plate and the bottom probe plate are disposed such that the entrance surfaces (i.e., the surface associated with the entry of the laser into the material) of these probe plates are adjacent to one another. The exit surfaces (i.e., the surface associated with the exit of the laser from the material) face away from one another. As such, the smaller exit portions of the holes are further apart than the larger entrance portions of the holes. Spacing the exit holes relatively far from one another provides a relatively high lateral stability of the probes.

According to one embodiment, the space transformer is configured to decrease the density and/or the pitch of the electrical contacts of the probe cards. More specifically, the plurality of probes might have a first density (or probe density) and/or first pitch (i.e., probe pitch) that are respectively higher than a second density (or PCB contact density) and/or second pitch (i.e., PCB contact pitch) of a plurality of PCB contact pads 205 that are disposed on the bottom surface of the PCB. Contact pads 205 are annular rings according to one embodiment of the present invention. One contact pad 205a is shown in FIG. 2. More specifically yet, referring to FIG. 2, the space transformer includes a bottom-contact pad 210 for each probe (e.g., probe 115a). According to the example being considered, a first tip 115a′ of probe 115a is configured to contact the bottom-contact pad 210. A second tip 115a″ of the probe is configured to extend from the bottom of the probe card and to contact a bond pad of a wafer. Bottom-contact pad 210 of the space transformer may be coupled to a trace 215, which is disposed on the bottom surface of the space transformer. Trace 215 may be coupled to a via 220, which extends from the bottom surface of the space transfer to the top surface of space transformer. The via may be coupled to a top-contact pad 225 that is disposed on the top surface of the space transformer. While trace 215 is shown in FIG. 2 as being disposed on the bottom surface of the space transformer, the trace may be disposed on the top surface of the space transformer or may be disposed on an inner layer of the space transformer. Various traces of the space transformer may be disposed on the top surface, the bottom surface, and/or in inner layers. According to one embodiment, at least one bottom-contact pad of the space transformer is coupled to a via of the space transformer that is in turn coupled to a top-contact pad of the space transformer without an intervening trace (e.g., see in FIG. 1 the top and the bottom contact pads associated with probe 115d, and see the via that couples these contact pads).

According to one embodiment, the top-probe plate and the bottom-probe plate are coupled by one or more fasteners 230, such as screws, clamps, or the like (see FIG. 1A). The PCB and space transformer may be coupled by one or more fasteners, such as screws, clamps, or the like. The coupled PCB and space transformer may then be coupled to the top and bottom-probe plates by one or more fasteners 235, such as screws, clamps, or the like. The coupled PCB and space transformer may be separable from the top-probe plate and the bottom-probe plate to permit the relatively easy change of one or more probes. For example, probes may be replaced is they are damaged, the lengths of the probes are changed or the like.

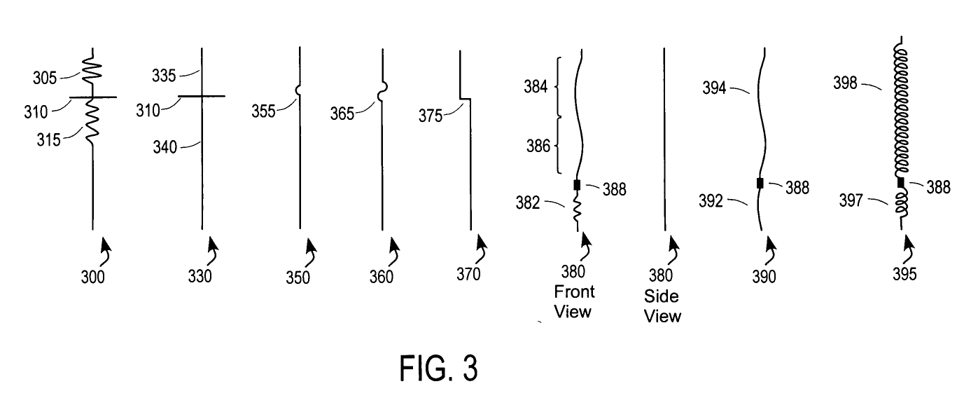

FIG. 3 is a simplified side view of a variety of probes according to a variety of embodiments of the present invention. The probes have a variety of shapes according to various embodiments. For example, probe 300 includes a top-spring portion 305, a lateral support 310, and a bottom-spring portion 315. The top and bottom-spring portions may be coiled, serpentined, or the like to permit these portions of the probe to vertically compress. For example, the top-spring portion may compress as the space transformer is coupled to the top and bottom-probe plates. The bottom spring portion may be configured to compress as the probe contacts the bond pad of an IC. Lateral support 305 may be configured to contact the exit surface of the top-probe plate to prevent the probe from falling out of the probe card.

Further, probe 330 includes a top portion 335 and a bottom portion 340 that are straight. Probe 330 may also include a lateral support 310 (describe above). The top and bottom portions of probe 330 might be configured to laterally bend under linear compression forces (e.g., a force that is substantially along a longitudinal axis of the probe). The lateral bend of the top or bottom portion of the probe provides a spring action for the probe. For example, as the space transformer is coupled to the top and bottom-probe plates, and as the bottom-contact pads 210 press on the tips 115a′ of the probes (e.g., the top portion of probe 330), the top portions of the probes might be configured to laterally bend under the compression force. The bottom portions of the probes 330 might be configured to laterally bend as the probes are pushed to contact the bond pads of an IC. According to one embodiment, the bottom-contact pads of the space transformer press on the tip of the probes with sufficient force such that the tips of the probes are held to the space transformer's bottom-contact pads and substantially do not scratch the bottom-contact pads. That is, each tip contact its associated bottom-contact pad of the space transformer in an area that is about the size of the tip, and the tip substantially does not move from the area so that the bottom-contact pad of the space transformer is not scratched. For example, as the probes are pushed to contact the bonding pads of a wafer, the tip of the probes in contact with the bottom-contact pads of the space transformer will substantially not scratch the bottom-contact pads. The top portion of each pin that is between the space transformer and the lateral support is constrained with a higher compression force, which is applied by the space transformer, than the compression force on the bottom portion of the probes that is applied by pushing the probes into contract with bond pads of a wafer.

Probe 350 includes a lateral support 355 that is curved and that may be configured to compress as the space transformer is coupled to the top and bottom-probe plates. Probe 360 includes a lateral support 365 that includes two curved portions that may be configured to compress as the space transformer is coupled to the top and bottom-probe plates. Probe 370 has a step shape that is provided by a lateral support 375. The probes shown in FIG. 3 are exemplary and those of skill in the art will know of other useful probes and these probes are considered to be within the scope and purview of the present invention. Each of probes 350, 360, and 370 includes straight top and bottom portions, such as those of probe 330 described above. Alternatively, probes 350, 360, and 379 may include top and/or bottom portions that have coil shapes, serpentine shapes or the like, such as those top and bottom portions of probe 300 discussed above.

Probe 380 includes a bottom portion 382 that may be coiled, serpentine, or the like, and includes a top portion that may include a first laterally bent portion 384 and/or a second laterally bent portion 386. Probe 380 may include a lateral support 388.

Probe 390 includes a bottom portion 392 that may be arced with a single arc, and includes a top portion 394 that includes a one or more arced portions. Probe 390 may include a lateral support 388.

Probe 395 includes a bottom portion 397 that may be a spring, such as a micro spring, and includes a top portion 398 that me be a spring, such as a micro spring. The micro springs may be of the type manufactured by Microfabrica Inc. of Van Nuys, Calif. A tip 399 that is substantially vertical (e.g., vertical with respect to the plane of the drawing sheet) may coupled to the tip of each spring. Probe 390 may include a lateral support 388.

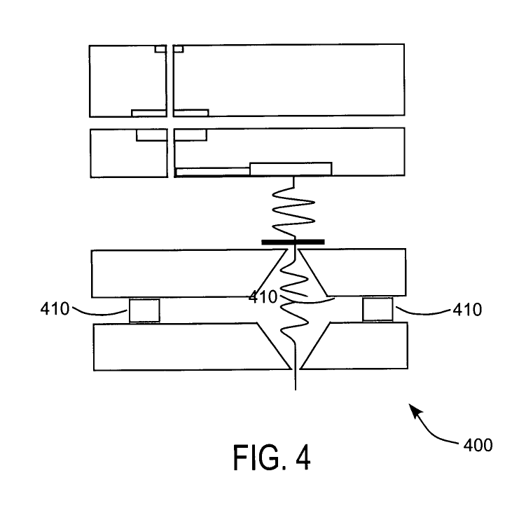

FIG. 4 is a simplified cross-sectional view of a portion 400 of a probe card according to another embodiment of the present invention. The probe card to which probe card portion 400 belongs differs from the probe card embodiments described above in that the probe card includes a set of spacers 410 disposed between the top-probe plate and the bottom-probe plate. A set as referred to herein includes one or more members. The spacers are configured to provide a space between the top and bottom-probe plates. The space provided by the spacers may be configured to permit probes of a variety of lengths to be used with the probe card. The space provided by the spacers may also permit relatively more lateral bend of the probes.

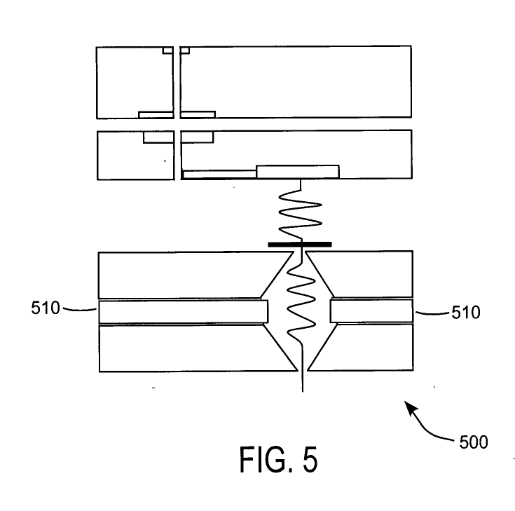

FIG. 5 is a simplified cross-sectional view of a portion 500 of a probe card according to another embodiment of the present invention. The probe card to which probe card portion 500 belongs differs from the probe card embodiments described above in that the probe card includes a spacer 510 disposed between the top-probe plate and the bottom-probe plate. A plurality of holes is formed in the spacer and each hole is located at a position where one of the probes is located. Similar to the set of spacers 510 described above, spacer 510 is configured to permit probes of a variety of lengths to be used with the probe card, and may also permit relatively more lateral bend of the probes.

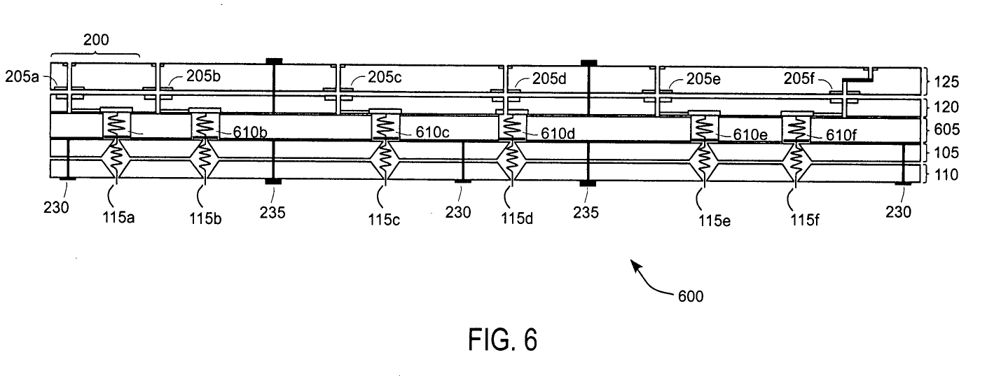

FIG. 6 is a simplified cross-sectional view of a probe card 600 according to another embodiment of the present invention. The same numeral scheme used in FIG. 1A is used in FIG. 6 to identify substantially similar parts of probe cards 100 and 600. Probe card 600 differs from the probe cards described above in that probe card 600 includes a spacer plate 605. Spacer plate 605 is positioned between space transformer 120 and top probe plate 105. A plurality of holes 610 are formed in the space transform. The holes may be formed by laser drilling or by other methods. Holes 610 are formed so that the top portions of the probes fit through the holes. Probe card 600 may includes spacers 410 or 510.

According to one embodiment of an assembly method for assembling anyone of the foregoing described probe cards, first, the top-probe plate and the bottom-probe plate may be coupled. The top-probe plate and the bottom-probe place may be moved laterally with respect to one another as or after these probe plates are coupled. The top-probe plate and/or the bottom-probe plate may be coupled to one or more stages (e.g., micrometer stages) that are configured to laterally translate these plates in one or more lateral directions. The plates may be laterally moved by the one or more stages to adjust the positions of the holes in the top-probe plate relative to the holes in the bottom-probe plate. Via the movement of these holes relative to one another, the vertical angles of the probes may be adjusted and thereby, the positions of the tips of the probes may be adjusted to align the probes with a set of bond pads on a wafer. While the foregoing embodiment is described as including the use of stages to move the top and bottom-probe plates relative to one another, these plates might be moved and/or aligned by other methods that will be well known to those of skill in the art and are to be considered within the scope and purview of the present invention. Subsequent to coupling the top-probe plate to the bottom-probe plate, the probes may be placed in the holes formed in these plates. Thereafter, the space transformer may be coupled to the assembled top and bottom-probe plates. The PCB may then be coupled to the space transformer. Alternatively, the coupled PCB and space transformer may be coupled as a single unit to the top and bottom-probe plates. The spacers and/or the spacer plate may be coupled to their associated components at the various assembly steps as will be understood by those of skill in the art.

According to one embodiment, the space transformer is a ceramic or flexible circuit board, and may be a low temperature co-fired ceramic (LTCC). The PCB may be formed from a variety of well known materials such as fiber glass, polyimide, polyester or the like. The probes may be tungsten, nickel, beryllium copper, a combination of the foregoing or other known probe material.

It is to be understood that the exemplary embodiments described above are for illustrative purposes only and that various modifications or changes in light thereof will be suggested to persons skilled in the art and are to be included within the spirit and purview of this application and scope of the appended claims. Therefore, the above description should not be understood as limiting the scope of the invention as defined by the claims.

What is claimed is:

1. A probe card comprises:
a first probe plate having a first plurality of tapered apertures formed therein, wherein i) each of the tapered apertures has a first opening that is smaller than a second opening, and ii) the first openings and the second openings are on opposite surfaces of the first probe plate;
a second probe plate coupled to the first probe place and having a second plurality of tapered apertures formed therein, wherein i) each of the tapered apertures has a first opening that is smaller than a second opening, ii) the first openings and the second openings are on opposite surfaces of the second probe plate, iii) the surfaces having the second openings are disposed adjacent to one another, and iv) pairs of the tapered apertures of the first and second probe plates substantially align; and
a plurality of probes, wherein each of the probes is disposed in one of the pairs of the tapered apertures.

2. The probe card of claim 1, further comprising a space transformer having a plurality of pads disposed on a first surface of the space transformer, wherein each of the pads is configured to contact a first end of each of the probes.

3. The probe card of claim 2, wherein each probe includes a lateral support that is configured to permit the force applied to the probe by the space transformer to be different than the force applied to the probe by a bond pad of an integrated circuit.

4. The probe card of claim 3, wherein a portion of each probe between the space transformer and the lateral support is constrained with a higher compression force than a compression force applied to the probe by a bond pad.

5. The probe card of claim 3, wherein the higher compression force inhibits scratching of the plurality of pads.

6. The probe card of claim 2, wherein the surface of the second probe plate that includes the first openings is a first surface of the probe card, and a second end of each of the probes is configured to extend from the first surface of the probe card.

7. The probe card of claim 2, wherein the space transformer includes a second plurality of pads disposed on a second surface, which is disposed opposite the first mentioned surface of the space transformer.

8. The probe card of claim 7, further comprising a printed circuit board (PCB) coupled to the space transformer, wherein the PCB includes a plurality of pads, which is configured to respectively couple to the second plurality of pads of the space transformer.

9. The probe card of claim 7, wherein a density of the plurality of pads of the PCB is less than a density of the first plurality of the pads of the space transformer.

10. The probe card of claim 1, wherein each probe includes a lateral support that is configured to couple to a surface of the first probe plate that includes the first opening of the first probe plate.

11. The probe card of claim 10, wherein the lateral support of each of the probes is configured to inhibit the probe from dislodging from the first and second probe-plates.

12. The probe card of claim 11, wherein the lateral support is straight, curved, and/or has a spring configuration.

13. The probe card of claim 1, wherein each of the probes includes a top portion that has a spring configuration and the top portion is configured to flex if the probe is pressed by the space transformer.

14. The probe card of claim 11, wherein the top portion is straight, coiled, serpentine, or is a micro spring.

15. The probe card of claim 13, wherein each probe includes a bottom portion that has a spring configuration and the bottom portion is configured to flex if the probe presses a bond pad of an integrated circuit.

16. The probe card of claim 15, wherein the bottom portion is straight, coiled, serpentine, or is a micro spring.

17. The probe card of claim 1, wherein the first and the second pluralities of tapered apertures are formed by laser ablation.

18. The probe card of claim 1, wherein the probes inserted into the pairs of tapered apertures are configured to be removable and replaceable.

19. A probe card comprises:
a first probe plate having a first plurality of tapered apertures formed therein, wherein i) each of the tapered apertures has a first opening that is smaller than a second opening, and ii) the first openings and the second openings are on opposite surfaces of the first probe plate;
a second probe plate having a second plurality of tapered apertures formed therein, wherein i) each of the tapered apertures has a first opening that is smaller than a second opening, ii) the first openings and the second openings are on opposite surfaces of the second probe plate, iii) the surfaces having the second openings are disposed adjacent to one another, and iv) pairs of the tapered apertures of the first and second probe plates substantially align;
a plurality of probes, wherein each of the probes is disposed in one of the pairs of the tapered apertures;
a space transformer coupled to the first probe plate and having first and second opposed surfaces that respectively include a first and a second plurality of pads, wherein each of the first pads is coupled to a first end of each of the probes; and
a printed circuit board (PCB) coupled to the space transformer and having first and second opposing surfaces, wherein the first surface includes a pluralities of pads that are respectively coupled to the second plurality of pads of the space transformer.

20. The probe card of claim 19, wherein the second surface of the PCB is a top surface of the probe card and the surface of the second probe plate that includes the first openings is a bottom surface of the probe card and the probes extend from the bottom surface.

21. The probe card of claim 19, wherein the probes inserted into the pairs of tapered apertures are configured to be removable and replaceable.
